(19) United States
(12) Patent Application Publication
(10) Pub. No.: US 2026/0276363 A1
(43) Pub. Date: Sep. 17, 2026

(54) SENSING DEVICE

(71) Applicant: Carnegie Mellon University, Pittsburgh, PA (US)

(72) Inventors: Lu Li, Pittsburgh, PA (US); Victoria Webster-Wood, Pittsburgh, PA (US); Howie Choset, Pittsburgh, PA (US); Kevin Dai, Pittsburgh, PA (US); Xinyu Wang, Pittsburgh, PA (US)

(73) Assignee: Carnegie Mellon University, Pittsburgh, PA (US)

(21) Appl. No.: 19/469,506

(22) PCT Filed: Mar. 28, 2024
(86) PCT No.: PCT/US2024/022099

§ 371 Date: Sep. 26, 2025

Related U.S. Application Data
(60) Provisional application No. 63/455,133, filed on Mar. 28, 2023.

(51) Int. Cl. G01B 7/34

(52) U.S. Cl. CPC G01B 7/34

(57) ABSTRACT

A tactile sensor utilizes a magnet embedded in an elastomer and a magnetometer for measuring a strength of a magnetic field emitted by the magnet. The elastomer may include two layers, with a first layer having a lower modulus than the second layer. When two layers are used, the magnet can be positioned at an interface between the layers. The use of a softer outer layer increases the sensitivity of the sensor. Sensitivity can be further increased by including features or a pattern of features on the surface of the elastomer. The features, which can be similar to fingerprints on a human hand, are adapted to provide vibrational information caused by the surface roughness of a material. The sensor provides material characterization and can be used to identify the material in contact with the sensor. The sensor can be fabricated using molding techniques.

### CROSS-REFERENCE TO RELATED APPLICATIONS

This application claims the benefit under 35 U.S.C. § 119 of U.S. Provisional Application Ser. No. 63/455,133, filed on Mar. 28, 2023, which is incorporated herein by reference.

### STATEMENT REGARDING FEDERALLY SPONSORED RESEARCH

This invention was made with United States government support under Grant No. DGE1745016 awarded by the National Science Foundation Research Fellowship Program. The government has certain rights in the invention.

### BACKGROUND OF THE INVENTION

The present disclosure generally relates to tactile sensors. More specifically, the disclosure relates to a tactile sensor that can be used to identify the characteristics of a material through contact between the sensor and the material.

Tactile sensing typically involves active exploration of unknown surfaces and objects, making it especially effective at processing the characteristics of materials and textures. A key property extracted by human tactile perception in material classification is surface roughness, which relies on measuring vibratory signals using the multi-layered fingertip structure. Existing robotic systems lack tactile sensors that are capable of providing high dynamic sensing ranges, perceive material properties, and maintain a low hardware cost.

While humans rely on a complex hierarchical haptic system to understand the physical world, many robots lack this ability, relying instead on computer-vision approaches. Implementation of haptic force feedback and surface roughness detection could improve robot utility in active exploration by increasing gripping stability during manipulation, reducing risk of unsafe human-robot interactions, and automating surface quality control processes. Additionally, robots equipped with cutaneous tactile sensing could be well-suited to teleoperation with simultaneous rendering of haptic virtual environments including surface textures.

To address the need for tactile sensation in robots, previous works in tactile sensors have used a variety of technologies such as resistive, optical, and capacitive sensing, resulting in sensors with range of functionality, resolution, and cost. Specifically, visual-tactile sensors can provide high resolution texture information but can be costly, bulky, and require complex computational overhead for processing data. In scenarios where robots physically manipulate objects, vision-based systems may be insufficient for measuring mechanical properties compared to the performance of vibrotactile touch sensors. And multimodal sensors combine many aspects of sensor technology to enable collection of a range of materials' mechanical and thermal properties, and are available in a biomimetic form factor, but require high cost and complexity of fabrication.

It would therefore be advantageous to develop a high resolution and high dynamic range but low-cost tactile sensor for precise determination of applied forces and torques as well as surface texture classification.

### BRIEF SUMMARY

According to embodiments of the present disclosure is a sensor utilizing a magnet embedded in an elastomer. A magnetometer detects magnetic field gradients corresponding to magnet movement in response to deformation of the elastomer. Deformation occurs when the sensor contacts an object or a surface of an object, such as when a robotic gripper having a sensor grips an object. Multiple degrees of freedom enable the sensor to determine contact direction, force, and torque in multiple dimensions. In some embodiments, the capabilities of the sensor are extended by adding biomimetic features, including fingerprint ridges. Further, two layers of elastomer with different moduli can be used to increase sensitivity. The sensor can be fabricated in a molding technique. The sensor is capable of detecting high-resolution magnetic field data through the Hall effect and creating high-dimensional time-frequency domain features for material texture classification.

### BRIEF DESCRIPTION OF THE SEVERAL VIEWS OF THE DRAWINGS

FIG. 1 is a tactile sensor according to one embodiment.

FIG. 2 depicts features on a surface of different sensors.

FIG. 3 is a graph depicting the classification accuracy of the sensors depicted in FIG. 2.

FIGS. 4A-4E are graphs of data transformed during data processing steps.

FIGS. 5A-5B show a sensor utilized in a robotic gripper (FIG. 5A) and an alternative embodiment of the sensor (FIG. 5B) used in the gripper.

FIG. 6 shows a mold used in the fabrication of the sensor.

### DETAILED DESCRIPTION

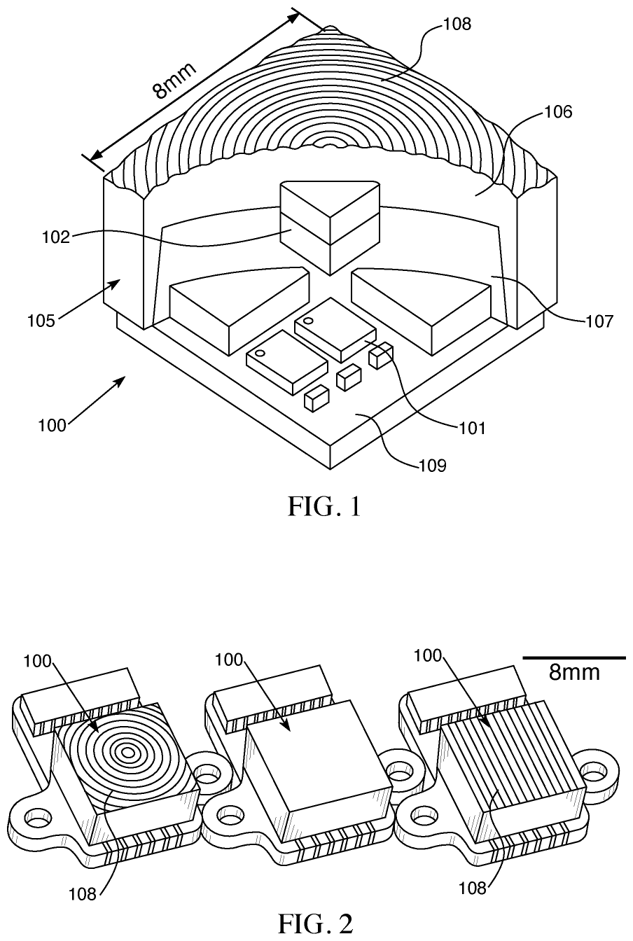

According to embodiments of the disclosure is a sensor 100 comprising a magnet 102 embedded in an elastomer 105, as shown in FIG. 1. The magnet 102 is positioned near a magnetometer 101, such as a Hall effect sensor, or an array of magnetometers 101 which are capable of measuring the magnetic field associated with the magnet 102. When contact between the sensor 100 and a surface occurs, the elastomer 105 deforms, causing a change in the position of the magnet 102 relative to the magnetometer 101. The magnetometer 101 will record the resulting change in the magnetic field. In some embodiments, the magnetometer 101 will provide data about the magnetic field including strength, direction, and relative change in strength for each of the X, Y, and Z axis. Data processing can be used to determine surface characteristics based on the magnetic field measurements. In some embodiments, the surface of the elastomer 105 contains features 108, such as fingerprints, to accentuate surface roughness, which manifests as vibrations when the sensor 100 is moved across the surface.

In one example embodiment, the tactile sensor 100 comprises a magnetometer 101 (Melexis MLX90393) and a magnet 102 embedded within an elastomer 105 that is attached to a printed circuit board (“PCB”) 109. When force is applied to the elastomer 105, the elastomer 105 deforms and moves the magnet 102, thereby changing the magnetic field detected by the magnetometer 101 through the Hall effect.

As shown in FIG. 1, the elastomer 105 may comprise a first layer 106 and a second layer 107. The geometry of the tactile sensor's elastomer layers 106/107 are designed to mimic the structure of a human finger's epidermis and dermis layers. The first layer 106 (i.e. epidermis layer) is 2 mm thick and the second layer 107 (i.e. dermis layer) is 3 mm thick. The thickness may vary depending on the application and expected forces, with ranges from less than a millimeter to several millimeters. In addition, multiple layers (i.e. >2 layers) can be created in the elastomer 105 or a gradient in the elastomer 105 can be created without using distinct layers. A 2 mm N50 cube magnet 102 (SuperMagnetMan C0020) is centered between the layers 106/107. In some embodiments, the external surface of the epidermis layer 106 is curved to represent the curvature of human fingers and/or patterned with ridges 108 to represent human fingerprint ridges with a depth of 80 μm, width of 400 μm, and wavelength of 600 μm, as shown in FIG. 2. In FIG. 2, the left-most sensor 100 has a spherically curved surface with fingerprint ridges 108, the middle sensor 100 is flat without ridges 108, and the right-most sensor 100 is flat with fingerprint ridges 108 on the surface of the epidermis layer 106 of the elastomer 105.

The pattern of the features 108 on the surface of the elastomer can take several shapes. Depicted in FIG. 2 are parallel ridges 108 and circular ridges 108. The pattern can vary depending on the intended application, the sensitivity of the magnetometer, and the surface roughness of the material expected to be characterized by the sensor 100. For example, in one embodiment, the ridges 108 are taller than 80 μm and have a spacing greater than 600 μm. By way of further example, parallel fingerprint ridges 108 can be molded either aligned with or perpendicular to the scanning direction; radially symmetric rings of concentric ridges 108 can be molded; discontinuous ridges or bumps 108 can be molded; aligned swirls 108 such as found on human fingerprints can be molded. In each of these examples, the spacing between and height of ridges or bumps 108 can be varied.

The tactile sensors 100 can be fabricated through injection molding. At a first step, the PCB 109 is placed into a mold 210 or adjacent to a mold 210 having an internal cavity defining the dermis layer 107. Next, the elastomer 105 is cast onto the PCB 109, which contains the magnetometer 101, to encapsulate the magnetometers 101 in the dermis layer 107. In this two-stage process, a separate mold 210 is used to cast each of the layers 106/107 of the elastomer 105. During this two-step process, the magnet 102 is placed on or near the dermis layer 107 after it is formed, which places the magnet 102 at the interface or border between the two layers 106/107. After placing the magnet 102, the epidermis layer 106 is cast using a second mold 210 having a shape of the epidermis layer 106. This mold 210 may contain a pattern of features to form the fingerprint 108 on the surface of the elastomer 105 forming the epidermis layer 106.

In an alternative embodiment, the two layers 106/107 are separated by a divider 110 and both layers 106/107 can be molded simultaneously. FIG. 6 depicts a single mold 210 having the divider 110 separating the mold 210 into two sections, a first section 211 and a second section 212. In this embodiment, the magnet 102 can be attached to the divider 110, further simplifying the molding process. With the first section 211 and section 212 separated, liquid elastomers can be poured into each section 211/212 to form the epidermis 106 and dermis 107 layers without cross-contamination prior to curing of the elastomers 105.

Referring again to the two-step process, the molds 210 can be mounted to the PCB 109 along with a silicone gasket and a rigid acrylic backing plate to prevent elastomer 105 leakage during casting. The epidermis layer 106 (Young's Modulus, E≈145 psi) can be fabricated using Smooth-On Mold Star 30 (E=96 psi) and the dermis layer 107 (E≈20 psi) can be fabricated using Ecoflex 00-10 (E=8 psi). To adhere the elastomer 105 to the sensor PCB 109, coupling agents or primers such as DOWSIL 1200 OS primer can be applied to the PCB 109 prior to casting. A magnet 102 is encapsulated in the sensor 100 by placing the magnet 102 in a cavity in the dermis layer 107 casting prior to casting the epidermis layer 106.

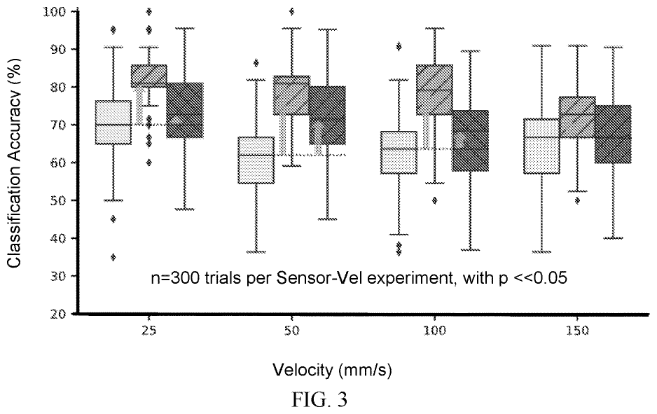

Using the sensor 100, material classification is performed using data obtained from the sensor 100 without the need for calibration or simulation. By way of further example, the results of material classification using the sensor 100 is depicted in FIG. 3, where three different sensors 100 with differing surface patterns 108 were tested at a range of scanning velocities. As shown in FIG. 3, the sensors 100 with fingerprint patterns 108 (middle and right) exhibited greater accuracy than a sensor without a fingerprint feature 108 (left). The data appearing in FIG. 3 was collected by mounting a sensor 100 to a moving platform and pressed against different surfaces. The platform was moved at a range of scanning velocities to simulate the process a human would do when analyzing a surface.

During this demonstration, data was collected for each sensor 100 on six material samples of different roughness: three acrylic samples, two wood samples, and one aluminum sample. Table II shows the material surface roughness characteristics, including average roughness (Ra), the total height of the roughness profile (Rt), and the maximum profile peak (Rp):

| Material | Description | Ra (μm) | Rt (μm) | Rp (μm) |
|---|---|---|---|---|
| Aluminum | Un-etched | 0.795 | 9.37 | 3.68 |
| Wood | Un-etched | 5.74 | 45.3 | 14.6 |
| Acrylic | Lines, 1.3 mm | 7.04 | 110 | 18.7 |
| Acrylic | Lines, 0.5 mm | 10.9 | 71.6 | 31.1 |
| Acrylic | Cross-hatched | 15.3 | 264 | 52.6 |
| Wood | Roughly-etched | 23.8 | 180 | 51.5 |

During each trial, the sensor 100 was homed to identify the surface contact Z position. Surface contact was determined by calculating the exponential moving average (a=0.12) of the sensor's Z axis magnetic field reading. A contact detection threshold of 10 LSB was set after determining that it corresponded to a contact force of 1.53±0.41 g. For each trial the sensor 100 was tested for 3 consecutive repetitions in both positive and negative X-direction translation at 25 mm/s, 50 mm/s, 100 mm/s and 150 mm/s to mimic human exploratory surface scanning speeds.

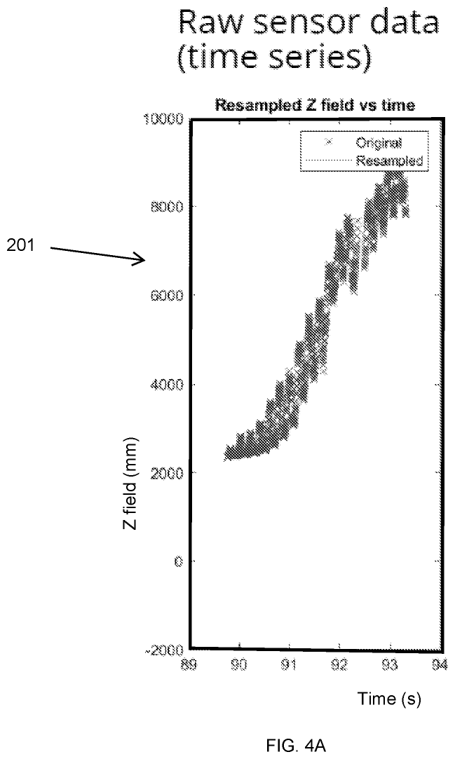

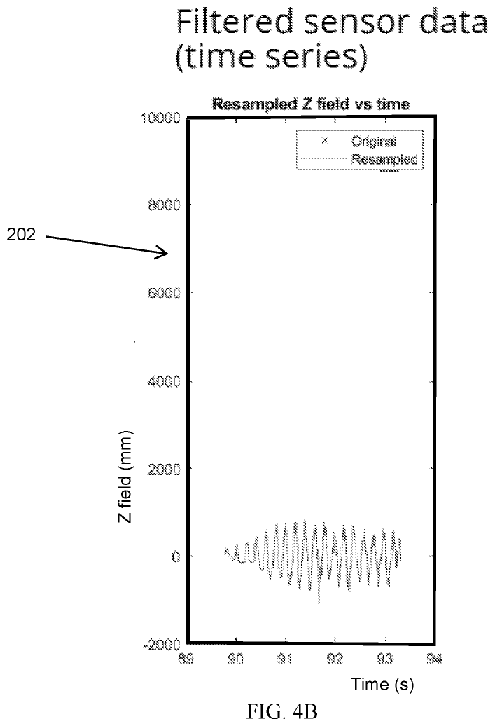

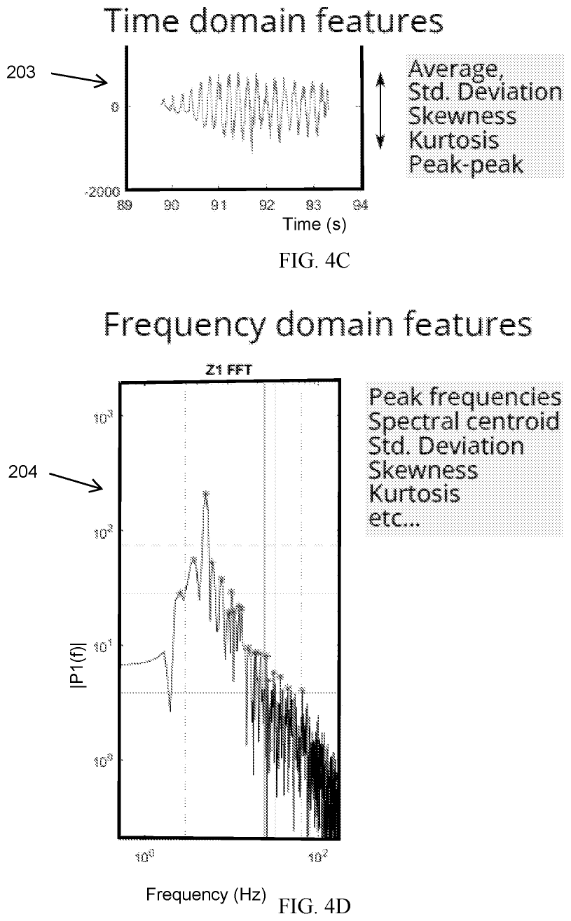

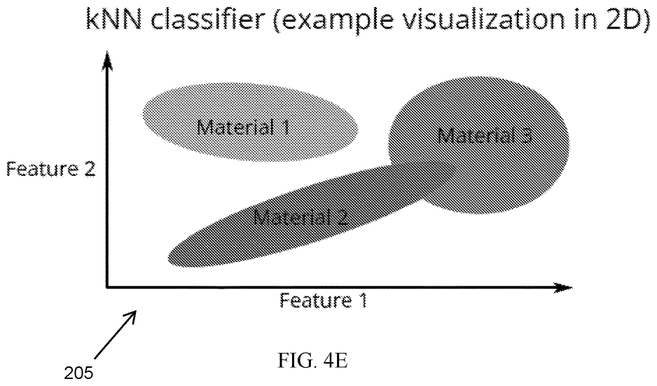

Data extracted from the magnetometer 101 includes magnetic field readings in the sensor's X, Y, and Z axes. Representative data obtained from the magnetometer 101 is depicted in FIG. 4A. From this data, the displacement and angular rotation of the magnet can be determined. Data processing continues by calculating the 3-axis magnetic field time series data. The magnetometer 101 can sample data at around 333 Hz, although other sampling rates can be used depending on the application and acceptable computational costs. In one example, the sampling frequency can range from 10 Hz to 10,000 Hz.

The data is processed in both time domain and frequency domain (FFT). In one embodiment, the time series data is resampled for even spacing in time prior to FFT analysis. A 2 Hz high-pass filter can be applied to the data to remove DC effects. From the time series data, statistical features including mean, peak-peak amplitude, standard deviation, skewness, and kurtosis of magnetic field values are collected for each axis. From the FFT, statistical features including the spectral centroid, standard deviation, skewness, and kurtosis of the power spectrum along both the frequency axis and the power spectral density axis are collected. In addition, up to 20 of the largest peaks, if available, are located with at least 2 prominence in the FFT power spectrum. Then the statistical features of the 20 peaks along both the frequency axis and the power spectral density axis are extracted. Features with the same units were normalized together to a range of [0, 1] using minimum and maximum values.

FIGS. 4A-4E depict the steps 201 through 205 of data processing. At step 201, raw sensor data is acquired as a time series (FIG. 4A). Next at step 202, the raw sensor data is run through a highpass filter to produce a filtered time series (FIG. 4B). At step 203, a Fast Fourier Transform of the filtered time series data produces time domain features (FIG. 4C) (including average, standard deviation, skewness, kurtosis, and peak-peak) and frequency domain features (FIG. 4D) (including peak frequencies, spectral centroid, standard deviation, skewness, and kurtosis). At step 205, the time domain features and frequency domain features are used to classify the surface (FIG. 4E).

Classification of material surface properties is significantly improved when sensors 100 include biomimetic fingerprint ridges 108. Ridged sensors 100 classified surface wavelengths >8% more accurately than a flat, ridge-less sensor 100. The largest gap in performance can be observed at a velocity of 25 mm/s where the ridged sensor 100 resulted in a classification accuracy of 98.1±3.8%, whereas the flat sensor 100 had a classification accuracy of 85.4±7.9%.

As shown in the data depicted in FIG. 3, both ridged sensors 100 have higher material classification accuracy than the ridge-less sensor 100 at all scanning velocities. The flat sensor 100 with fingerprint ridges 108 maintains the highest classification accuracy with >7% improvement over the ridge-less sensor 100, but the gap in accuracy to other sensors 100 decreases at the highest scanning velocity. The difference in accuracy between the flat sensor 100 with ridges 108 and the spherical sensor 100 with ridges 108 suggests that the curved geometry may affect the distribution of contact forces acting on the spherical sensor 100 relative to the flat sensor 100. It is possible that insufficient contact pressure results in few ridges 108 interacting with the material samples and low vibration sensitivity. This difference may have advantages in some situations, such as when a very soft epidermis layer 106 is used or contact forces are expected to be low.

One advantage of the tactile sensor 100 is its independence from modeling for accurate classification results. Compared to other types of sensors, the sensor 100 of the present disclosure is not reliant on engineered models and does not require high resolution conversion between sensor readings and physical units. This allows users to avoid extremely time-consuming sensor calibration procedures against expensive ground truth force sensors. Further, there is not a noticeable correlation between sensor accuracy and surface roughness.

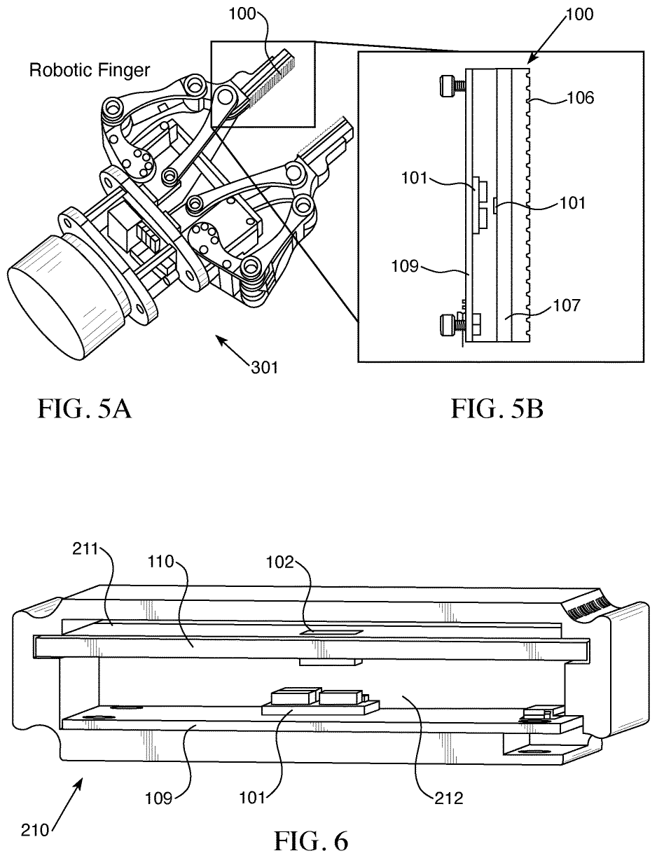

FIGS. 5A-5B show a sensor 100 utilized in a robotic gripper 301. The sensor 100 can be implemented in one or both sides of a parallel jaw robotic gripper 301. In this application, the sensor 100 may have to cover a larger area. In the example shown in FIGS. 5A-5B, the sensor 100 is 40 mm long, 20 mm wide, and 8.8 mm tall. As a result of this larger form factor, multiple magnetometers 101 can be used in the sensor 100. A rigid layer 110 between the first layer 106 and the second layer 107 of the elastomer 105 help to distribute the force within the elastomer 105. Additionally, a surface of the first layer 106 includes patterned features 108. The tactile sensor's sensitivity to contact forces or vibrations can be tuned by varying the material properties or geometry of the elastomer layers 106/107, changing the size or strength of the magnet 102, or by changing the sensitivity of the magnetometer 101.

In addition to the robotic gripper 301, the sensor 100 can be used in a variety of applications. For example, assembling wire harnesses is a critical step in the manufacturing process of automobiles and planes. Yet, this step of the manufacturing process is largely manual as it is not yet capable of automation. The tactile sensor 100 could be used in wire harness assembly by providing the requisite sensitivity and material identification. Other implementations can include anthropomorphic/humanoid robotic fingers or fingertips. In this example implementation, each fingertip on humanoid robot could include one or more sensors 100.

To further demonstrate the adaptability of the sensor 100, the sensitivity of the magnetometer 101 can be adjusted to account for different distances between the magnet 102 and the magnetometer. Further, the sensitivity of the magnetometer 101 can be adjusted to increase or decrease the range of forces that can be accommodated by the sensor 100. Likewise, the strength of the magnet 102 can be adjusted depending on the particular application. The strength of the magnet 102 can be adjusted by using different magnetic materials (i.e. ferromagnet, hard magnetic materials, etc.) or by using an electromagnet. One advantage of an electromagnet is that its magnetic field strength can be adjusted to overcome a background magnetic field. For example, if used in an industrial application where strong magnets are used, the electromagnet 102 can have a larger magnetic field to still provide usable data. The magnetic field of the electromagnet can also be varied in discernable patterns to provide a signal to the magnetometer 101.

In additional alternative embodiments, multiple magnetometers 101 are used with gradient-based classification features. This implementation may improve immunity to external magnetic fields. Further characterization of the sensor could modify sensor gains and stiffness for adjustable dynamic range and determine fatigue cycling effects.

When used in this specification and claims, the terms “comprises” and “comprising” and variations thereof mean that the specified features, steps, or integers are included. The terms are not to be interpreted to exclude the presence of other features, steps or components.

The invention may also broadly consist in the parts, elements, steps, examples and/or features referred to or indicated in the specification individually or collectively in any and all combinations of two or more said parts, elements, steps, examples and/or features. In particular, one or more features in any of the embodiments described herein may be combined with one or more features from any other embodiment(s) described herein.

Protection may be sought for any features disclosed in any one or more published documents referenced herein in combination with the present disclosure. Although certain example embodiments of the invention have been described, the scope of the appended claims is not intended to be limited solely to these embodiments. The claims are to be construed literally, purposively, and/or to encompass equivalents.

What is claimed is:

1. A sensor comprising:
a magnetometer;
an elastomer positioned adjacent to the magnetometer,
wherein a surface of the elastomer has a patterned feature; and
a magnet embedded within the elastomer.

2. The sensor of claim 1, wherein the patterned feature comprises a plurality of ridges.

3. The sensor of claim 1, wherein the elastomer comprises:
a first layer having a first modulus; and
a second layer having a second modulus greater than the first modulus, wherein the second layer is adjacent to the magnetometer.

4. The sensor of claim 1, wherein the magnet is positioned at an interface between the first layer and the second layer.

5. The sensor of claim 3, further comprising:
a rigid layer separating the first layer and the second layer.

6. The sensor of claim 5, wherein the magnet is embedded within the rigid layer.

7. The sensor of claim 1, further comprising a printed circuit board containing the magnetometer.

8. The sensor of claim 1, wherein the magnet comprises an electromagnet.

9. The sensor of claim 2, wherein each ridge of the plurality of ridges is parallel to an adjacent ridge.

10. The sensor of claim 2, wherein the plurality of ridges form a circular pattern.

11. A method of characterizing a surface using a sensor comprising:
acquiring a data from a sensor comprising a magnet embedded in an elastomer and a magnetometer, wherein the data comprises a time series;
filtering the data;
applying a fast Fourier transform to produce time domain features and frequency domain features;
classifying the surface using the time domain features and the frequency domain features.

12. The method of claim 11, wherein the time domain features comprise at least one of average, standard deviation, skewness, kurtosis, and peak-peak.

13. The method of claim 11, wherein the frequency domain features comprise at least one of frequencies, spectral centroid, standard deviation, skewness, and kurtosis.

14. The method of claim 11, further comprising:
adjusting a gain of the magnetometer.

15. The method of claim 11, wherein the magnet comprises an electromagnet and a field strength of the electromagnet is variable.

16. The method of claim 15, further comprising:
varying the field strength of the electromagnet in a pattern to create a data signal.

17. A method of fabricating a sensor comprising:
providing a first mold having an internal cavity defining a dermis layer;
placing a magnetometer adjacent to the first mold;
molding the dermis layer in the first mold, thereby encapsulating the magnetometer;
placing a magnet on the dermis layer;
providing a second mold having an internal cavity defining the epidermis layer, wherein the second mold contains a pattern;
molding the epidermis layer in the second mold, wherein a surface of epidermis layer has a fingerprint feature from the pattern of the second mold.

18. A method of fabricating a sensor comprising:
providing a mold having an internal cavity;
placing a magnetometer in the internal cavity;
placing a divider in the mold to form a first section and a second section of the internal cavity,
wherein the divider contains a magnet;
molding a first elastomer in the first section,
wherein molding the first elastomer forms a pattern of ridges on a surface of the first elastomer;
molding a second elastomer in the second section,
wherein the second elastomer is bound by the divider and the magnetometer.

19. The sensor of claim 1, wherein the sensor is incorporated into a robotic gripper.

20. The method of claim 11, wherein the surface is characterized during a wire harness assembly procedure.
